(19) United States
(12) Patent Application Publication
(10) Pub. No.: US 2026/0176749 A1
(43) Pub. Date: Jun. 25, 2026

(54) METHOD OF FORMING A STRUCTURE INCLUDING A METAL NITRIDE LAYER

(71) Applicant: ASM IP Holding B.V., Almere (NL)

(72) Inventors: Ali Al janabi, Scottsdale, AZ (US); Estiaque Haidar Shourov, Mesa, AZ (US); Mojtaba Samiee, Tempe, AZ (US)

(21) Appl. No.: 19/422,701

(22) Filed: Dec. 17, 2025

Related U.S. Application Data
(60) Provisional application No. 63/737,103, filed on Dec. 20, 2024.

(51) Int. Cl. C23C 16/34; C23C 16/44; C23C 16/455; C23C 16/56

(52) U.S. Cl. CPC C23C 16/34; C23C 16/4408; C23C 16/45553; C23C 16/56

(57) ABSTRACT

Methods for depositing a metal nitride film on a surface of a substrate are disclosed. Exemplary methods include providing a substrate into a reaction chamber and depositing a metal nitride film directly on the surface of the substrate by performing one or more cycles of a cyclical deposition process. The metal nitride film can form part of a gate structure in a semiconductor device.

### CROSS-REFERENCE TO RELATED APPLICATIONS

This application is a nonprovisional of, and claims priority to and the benefit of, U.S. Provisional Patent Application No. 63/737,103, filed Dec. 20, 2024 and entitled “METHOD OF FORMING A STRUCTURE INCLUDING A METAL NITRIDE LAYER,” which is hereby incorporated by reference herein.

### FIELD OF DISCLOSURE

The present disclosure relates generally to methods of forming structures, such as structures suitable for forming electronic devices. More particularly, the present disclosure relates to methods of forming structures that include a metal nitride layer.

### BACKGROUND OF THE DISCLOSURE

Deposition of metal-containing material, such as metal nitride material, can be used in the manufacture of a variety of devices, such as semiconductor devices, flat panel display devices and photovoltaic devices. For example, metal nitride material layer can be used as an etch stop layer or as a work function layer, in, for example, complementary metal-oxide-semiconductor (CMOS) structures.

A CMOS structure generally includes an n-type metal-oxide-semiconductor (NMOS) structure and a p-type metal-oxide-semiconductor (PMOS) structure. The PMOS and NMOS structures can include one or more work function layers to adjust a threshold voltage of the corresponding PMOS or NMOS device.

Various materials, such as titanium nitride (TiN), have been used as a p work function layer. While such materials may work for a variety of applications, use of typical p work function layers can result in a degradation of device performance, due at least in part, to a relatively high resistance of the p work function material. Additionally or alternatively, traditional work function layers may not exhibit a desired work function value for a given layer thickness.

Accordingly, improved methods are desired for forming structures with p work function layers that have relatively low resistivity and/or exhibit desired work function values and/or that mitigate degradation of device performance that might otherwise occur.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

In accordance with exemplary embodiments, a method of forming a structure is provided. An exemplary method includes providing a substrate, comprising a high-k layer, within a reaction chamber, and depositing a metal nitride layer overlying the high-k layer using a cyclical deposition process. In accordance with examples of the disclosure, the cyclical deposition process includes providing a metal precursor within the reaction chamber for a precursor pulse and providing a hydrogen and nitrogen reactant to the reaction chamber for a reactant pulse. In accordance with examples of these embodiments, the metal precursor is represented by the chemical formula:

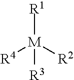

where M is Mo or W, and where each of R¹-R⁴ is independently selected from a C2-C7═N group or a C2-C7—O group of a C₁-C₄—N group. In some cases, the cyclical deposition process further includes purging the reaction chamber after the step of providing the hydrogen and nitrogen reactant and after the purging, providing a reducing agent to the reaction chamber. In some cases, a pressure within the reaction chamber during the step of providing a reducing agent to the reaction chamber increases over time. The step of depositing the metal nitride layer can be a thermal deposition process.

In accordance with further examples, the substrate comprises a liner layer overlying and in contact with the high-k layer. In accordance with additional examples, the method further includes forming a bulk conductive layer overlying and in contact with the metal nitride layer. The method can further include forming a bulk metal layer overlying the bulk conductive layer. In accordance with some examples, the method can also include forming an n work function layer overlying and in contact with the metal nitride layer. In accordance with further examples, the metal nitride layer forms an etch stop layer. In accordance with further examples, the metal nitride layer forms a p work function layer.

In accordance with some examples of the disclosure, the metal nitride layer can be an intrinsic work function layer. In some cases, the metal nitride layer can be a blocking layer.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

These and other embodiments will become readily apparent to those skilled in the art from the following detailed description of certain embodiments having reference to the attached figures; the invention is not limited to any particular embodiment(s) disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an exemplary method in accordance with embodiments of the disclosure.

FIG. 2 illustrates a structure in accordance with exemplary embodiments of the disclosure.

FIG. 3 illustrates a structure in accordance with additional exemplary embodiments of the disclosure.

FIG. 4 illustrates resistivity of a metal nitride layer in accordance with exemplary embodiments of the disclosure.

FIG. 5 illustrates XPS data of a metal nitride layer formed in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term substrate may refer to any underlying material or materials that may be used, or upon which, a device, a circuit, or a film may be formed.

As used herein, the term cyclical deposition may refer to the sequential introduction of precursors and/or reactants into a reaction chamber to deposit a film over a substrate and includes deposition techniques, such as atomic layer deposition (ALD) and cyclical chemical vapor deposition (cyclical CVD).

As used herein, the term cyclical chemical vapor deposition may refer to any process wherein a substrate is sequentially exposed to two or more volatile precursors, which react and/or decompose on a substrate to deposit a film.

As used herein, the term atomic layer deposition or ALD may refer to a vapor deposition process in which deposition cycles, typically a plurality of consecutive deposition cycles, are conducted in a reaction chamber. Generally, during each unit deposition cycle, a precursor is chemisorbed on a deposition surface (e.g., a substrate surface or a previously deposited underlying surface, such as material from a previous ALD cycle), forming a monolayer or sub-monolayer that does not readily react with additional precursor (i.e., a self-limiting reaction). Thereafter, if desired, a reactant (e.g., another precursor or reactant) may subsequently be introduced into the reaction chamber for use in converting the chemisorbed precursor to the desired material on the deposition surface. Typically, this reactant is capable of further reaction with the precursor. Purging steps may be utilized during each unit deposition cycle to remove excess precursor from the reaction chamber and/or remove excess reactant and/or reaction byproducts from the reaction chamber after conversion of the chemisorbed precursor. The term atomic layer deposition, as used herein, is meant to include processes designated by related terms, such as chemical vapor atomic layer deposition and the like, when performed with alternating pulses of precursor(s), reactant(s), and/or purge (e.g., inert carrier) gas.

As used herein, the term film and/or layer may refer to any physically continuous or physically discontinuous structures and materials formed by the methods disclosed herein. For example, film or layer could include 2D materials, nanolaminates, nanorods, nanotubes, or nanoparticles, or even partial or full molecular layers, or partial or full atomic layers or clusters of atoms and/or molecules. A film or layer may comprise material or a layer with pinholes, but still be at least partially physically continuous. The terms film and layer can be used interchangeably.

As used herein, the term metal nitride film or metal nitride may refer to a film comprising at least a metal component and a nitrogen component.

As used herein, the term metal precursor may refer to a precursor that comprises at least a metal component and another component, such as a ligand.

As used herein, the term reducing agent may refer to a reactant that donates an electron to another species in a redox chemical reaction.

As used herein, the term gas may refer to a vapor or vaporized solid and/or vaporized liquid and may be constituted by a single gas or a mixture of gases, depending on a context.

Exemplary embodiments of the present disclosure include methods that may be used to deposit a metal nitride film and to form related structures, such as structures suitable for forming device structures, such as MOS and CMOS structures. In some embodiments of the disclosure, the metal nitride film may form a portion of a gate stack, such as at least a portion of a gate electrode to a transistor device structure. The metal nitride film based gate electrode may provide a gate stack with a preferred effective work function for use in PMOS and/or NMOS devices.

The existing work function metals employed in the formation of gate electrodes may have limitations due to their unsuitable effective work function values. For example, it is known that the effective work function of a material may vary as a function of its thickness. Therefore, as device geometries decrease in advance technology nodes, the thickness of the corresponding device films, such as the work function metal(s) of the gate electrode, may also desirably decrease in thickness. The reduction in thickness may be associated with a change in the value of the effective work function of the overall gate stack. Such a change in the effective work function of the gate stack may result in a non-ideal effective work function for NMOS and/or PMOS device structures.

In some embodiments of the disclosure, electrical resistivity of the deposited metal nitride films may be an important parameter in improving structure or device efficiency, such as, for example, in applications wherein the metal nitride film may be utilized as a portion of a gate electrode or the like. As discussed above, next generation technology nodes may require ever decreasing film thicknesses. However, as the film thickness of a conductive film is decreased, the electrical resistivity of the conductive film may increase leading to efficiency losses in the associated semiconductor device structure. As a non-limiting example, the metal nitride films of the current disclosure may be utilized as a replacement for the common titanium nitride films currently employed in semiconductor device structures. The metal nitride films of the current disclosure may have a lower electrical resistivity compared with the electrical resistivity commonly achieved in titanium nitride films of comparable thickness.

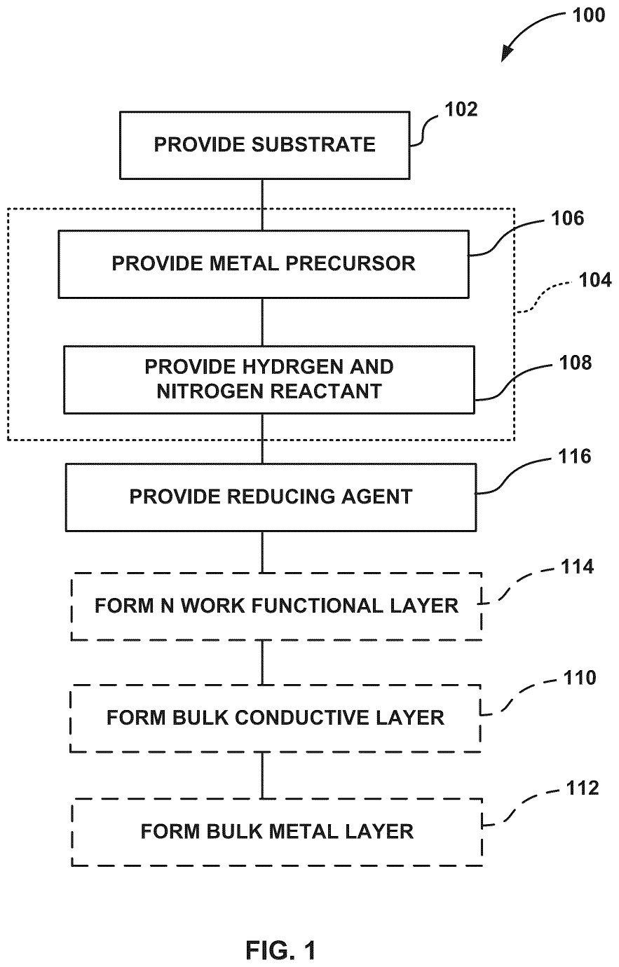

Turning to the figures, FIG. 1 illustrates a method 100 of forming a structure in accordance with examples of the disclosure. Method 100 can be used to deposit a metal nitride layer to form a structure, such as a structure including a gate feature that includes desired properties. In brief, method 100 includes providing a substrate in a reactor (step 102) and depositing a metal nitride layer (step 104).

During step 102, a substrate is provided within a reaction chamber. As noted above, the substrate can be of various forms and can include a bulk material and one or more layers and/or features formed within and/or overlying the bulk material. In accordance with examples of the disclosure, the substrate includes a high-k layer. Exemplary high-k materials for the high-k layer include lanthanum oxide or hafnium oxide. In some cases, the substrate can include a liner layer overlying and in contact with the high-k layer. Exemplary liners can be or include, for example, a metal nitride layer, such as a transition metal layer, such as titanium nitride. A thickness of the liner can be between about 5 Angstroms and about 15 Angstroms or between about 8 Angstroms and about 12 Angstroms.

The reaction chamber used during step 102 can be or include a reaction chamber of a vapor deposition reactor system configured to perform a cyclical deposition process. The reaction chamber can be a standalone reaction chamber or part of a cluster tool.

Step 102 can include heating the substrate to a desired deposition temperature within the reaction chamber. In some embodiments of the disclosure, step 102 includes heating the substrate to a temperature of less than 500° C. For example, in some embodiments of the disclosure, heating the substrate to a deposition temperature may comprise heating the substrate to a temperature between about 20° C. and about 500° C., less than 475° C., than 450° C., between about 150° C. and 450° C., between about 300° C. and 450° C., or between about 400° C. and 450° C.

In addition to controlling the temperature of the substrate, a pressure within the reaction chamber may also be regulated. For example, in some embodiments of the disclosure, the pressure within the reaction chamber during step 102 and/or at a beginning of step 104 may be less than 10000 Pa or between about 100 and about 10,000 Pa, or between about 240 and about 5,000 Pa.

During step 104, a metal nitride layer is deposited overlying the high-k layer. In accordance with examples of the disclosure, step 104 is a cyclical deposition process that includes one or more cycles, wherein one or more cycles include: providing a metal precursor within the reaction chamber for a precursor pulse (106), and providing a hydrogen and nitrogen reactant to the reaction chamber for a reactant pulse (108). In accordance with examples of the disclosure, the metal nitride layer is or includes one or more of molybdenum (Mo) or tungsten (W).

During step 106, a metal precursor is provided (e.g., pulsed) to the reaction space within the reactor. In accordance with various embodiments of the disclosure, the precursor includes one or more of a molybdenum and a tungsten. In other words, the metal-containing precursor includes one or more of a molybdenum precursor and a tungsten precursor. In some cases, the metal-containing precursor includes the molybdenum-containing precursor and the tungsten-containing precursor. In these cases, the molybdenum-containing precursor and the tungsten-containing precursor can be supplied to the reaction space/substrate concurrently or alternatingly and sequentially. A ratio of flowrates of the molybdenum precursor to the tungsten precursor can be from about 1 to 10 or about 1 to 1.

In accordance with various examples of the disclosure, the metal-containing precursor is or includes a compound having a chemical formula:

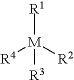

where M is Mo or W, and where each of R¹-R⁴ is independently selected from a C2-C7 (e.g., linear or branched alkane)═N group or a C2-C7 (e.g., linear or branched alkane)—O group or a C₁-C₄ (e.g., linear or branched alkane)—N group—e.g., where the O or Nis bonded directly to the metal. By way of examples, at least two of R¹-R⁴ are independently selected from a C₃-C₅ (e.g., linear or branched alkane)═N group and/or at least two of R¹-R⁴ are independently selected from a C₃-C₅ (e.g., linear or branched alkane)—O group and/or at least two of R¹-R⁴ are independently selected from a C₁-C₄ (e.g., linear or branched alkane)—N group. The ═N and/or —N groups and/or —O groups can be adjacent or opposed to each other.

By way of particular examples, the precursor can be or include one or more of bis(t-butylimido) bis(dimethylamino) molybdenum or bis(tert-butylimino)bis(tert-butoxy) Mo.

During step 106, the metal precursor can be provided to the reaction chamber with the aid of a carrier gas. The carrier gas can be or include, for example, argon and/or nitrogen in any mixture amount. A flowrate of the precursor to the reaction chamber during step 106 can be between about 30 and about 250 or between about 80 and 150 Torr. A duration of the precursor pulse can be between about 0.5 and about 20 or about 3 to 15 seconds.

During step 108, the hydrogen and nitrogen reactant is provided to the reaction chamber for a reactant pulse. In some cases, step 106 includes providing a gas that includes molecules that include both hydrogen and nitrogen, such as NH₃, N₂H₂ or a derivative thereof, and the like. In some cases, step 106 includes providing a gas that includes providing two gases, wherein at least one gas includes nitrogen (e.g., N₂, NH₃, N₂H₂, or a hydrazine derivative thereof), and at least one gas includes hydrogen (e.g., H₂, NH₃, N₂H₂, a derivative thereof or the like). In some embodiments, the hydrazine (N₂H₂) derivative may comprise an alkyl-hydrazine including at least one of: tertbutylhydrazine (C₄H₉N₂H₃), methylhydrazine (CH₃NHNH₂), 1,1-dimethylhydrazine((CH₃)₂N₂H₂), 1,2-dimethylhydrazine, ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl) hydrazine, 1-ethyl-1-(p-tolyl) hydrazine, 1-aminoimidazole, 1-amino-2,6-dimethylpiperidine, N-aminoaziridine, or azo-tert-butane.

In accordance with further examples, a sequence of providing the precursor, the nitrogen reactant, and the hydrogen reactant is: (A) precursor, (B) the nitrogen reactant, and (C) the hydrogen reactant (e.g., as a reducing agent during step 116).

During step 108, the reactant can be provided to the reaction chamber with a dilution gas. The dilution gas can be or include, for example, argon. A flowrate of the reactant to the reaction chamber during step 108 can be between about 3,000 and about 17,000 sccm. A duration of the reactant pulse can be between about 2 and about 20 seconds or between 5 and 20 seconds or between 10 and 12 seconds.

Step 104 can include purging the reaction chamber (e.g., using a vacuum source and/or an inert gas). An exemplary inert gas includes argon.

In some cases, the cyclical deposition process further includes purging the reaction chamber after the step of providing the hydrogen and nitrogen reactant and, after the purging, providing a step 116 of providing reducing agent to the reaction chamber—e.g., for a reducing agent pulser. The reducing agent can be selected from one or more of H₂, a cyclical reducing compound, such as 3,6-bis(trimethylsilyl)-1,4-cyclohexadiene, and mixtures thereof. A flowrate of the reducing agent to the reaction chamber during step 116 can be between about 3,000 and about 17,000 sccm. A duration of the reducing agent pulse can be greater than five seconds or between about 3 and about 20 seconds or between about 5 and about 20 seconds. A reducing agent pulse of greater than 5 seconds was found to produce metal nitride layers with desired resistivity and work function.

In accordance with examples of the disclosure, a pressure within the reaction chamber during the step of providing a reducing agent to the reaction chamber increases over time. For example, the pressure within the reaction chamber can (e.g., continually) increase by about 10 Torr, 20 Torr, 30 Torr, 50 Torr, 100 Torr or more during step 116. For example, a pressure can swing from less than 10 Torr or less than 5 Torr or less than 2.5 Torr to greater than 20 Torr, greater than 30 Torr, or greater than 40 Torr.

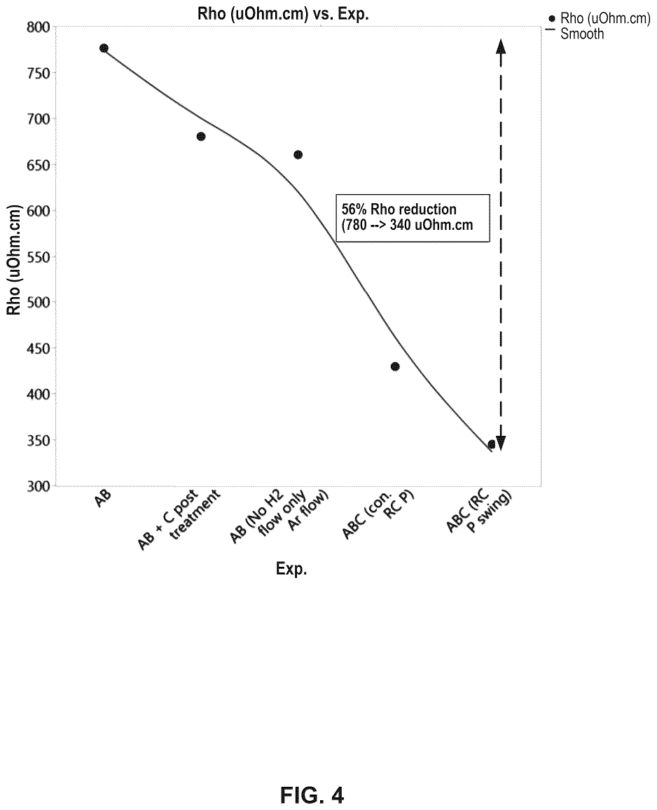

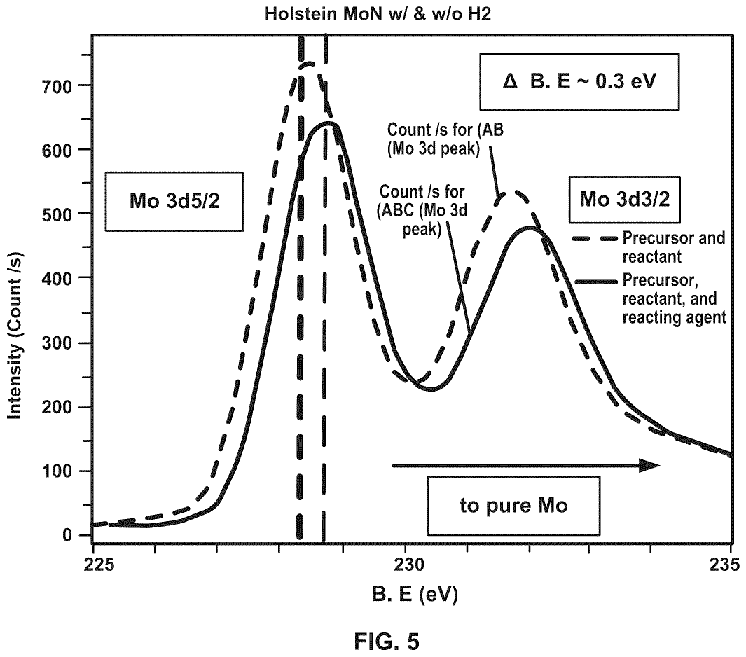

Using a hydrogen reactant as a reducing agent during a separate step 116 was found to increase Mo₂N phase structures and resulted in films with higher density (e.g., greater than 8.7 g/cc). FIG. 4 illustrates resistivity (μOhm.cm) as a function of process conditions. The same precursor and reactants were used for each condition. A reactant including NH₃ and a reducing agent comprising H₂ were used. The post treatment was a hydrogen anneal step as described herein. As illustrated, metal nitride layers formed using a step in which pressure increases while providing the reducing agent had the lowest resistivity values. FIG. 5 illustrates an increase in a metal (e.g., Mo) concentration with the addition of step 116.

In some cases, method 100 can include a post-deposition anneal process. Such a process can include heating the substrate to a temperature of about 350° C. to about 420° C. in a hydrogen environment. A hydrogen reactant as described above can be provided during this step. The post-deposition anneal can be a soak process, in which a pressure and/or amount of hydrogen reactant within the reaction chamber increases for a period of time—e.g., by throttling or closing an exhaust valve between the reaction chamber and a vacuum source.

A thickness of the metal nitride layer can be less than 20 Angstroms. For example, the thickness of the metal nitride layer can be greater than 1 Angstrom and less than 20 Angstroms, greater than 1 Angstrom and less than 10 Angstroms, or between 7 and 40 Angstroms. The metal nitride layer can form an etch stop layer and/or a p work function layer in a gate feature. A resistivity metal nitride layer is less than 650 μOhm.cm or less than 400 Ohm.cm or less than 300 μOhm.cm or less than 220 μOhm.cm and/or the eWF of structure including such layers can be +200 mEV, compared to TiN of the same thickness (for blocking) or +30 mEV or +20 mEV, compared to TiN of similar thickness. Films with the lowest resistivity were formed using a reducing agent and a pressure swing as described above.

In accordance with examples of the disclosure, film closure occurs at a film thickness of less than 15 Angstroms or less than 12 Angstroms.

In accordance with various examples of the disclosure, step 104 (e.g., depositing the metal nitride layer) is a thermal deposition process. In such cases, none of the precursor, reactant, or reducing agent are exposed to a plasma to form an excited species.

Method 100 can include a step 110 of forming a bulk conductive layer. The conductive layer can be formed overlying and in contact with the metal nitride layer. The bulk conductive layer can be formed of, for example, a transition metal nitride, such as, for example, titanium nitride, and can be deposited using any suitable technique, such as thermal ALD.

Method 100 can further include a step 112 of forming a bulk metal layer overlying the bulk conductive layer. The bulk metal layer can be formed of, for example, a transition metal, such as, for example, tungsten, and can be deposited using any suitable technique, such as sputter deposition.

In accordance with some examples of the disclosure, method 100 can include a step 114 of forming an n work function layer. The n work function layer can be formed overlying and in contact with the metal nitride layer. The n work function layer can be formed of, for example, TiAlC and can be deposited using any suitable technique, such as thermal ALD.

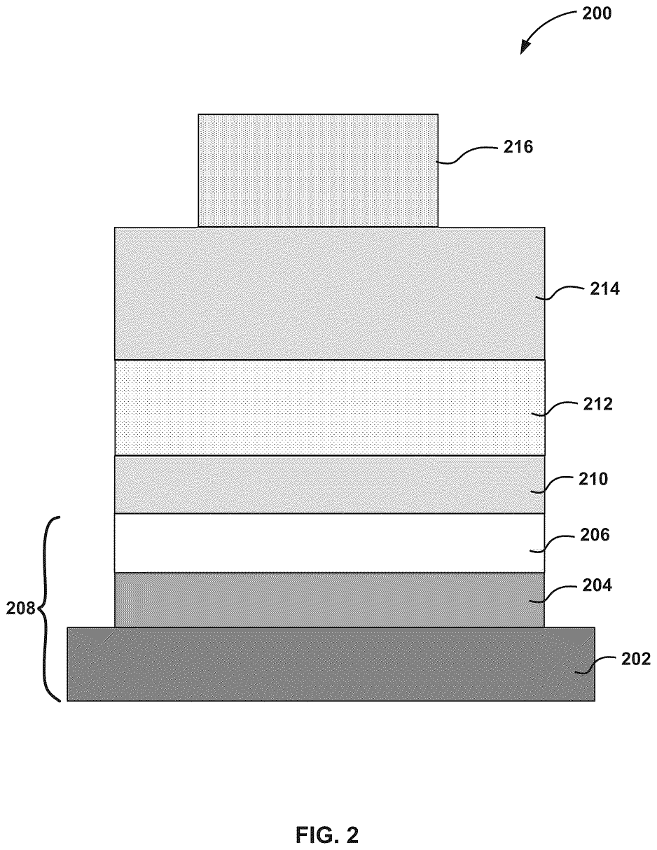

FIG. 2 illustrates a structure 200 in accordance with examples of the disclosure.

Structure 200 includes a substrate 202 (e.g., a layer or bulk semiconductor) having a first oxide (e.g., a silicon oxide or interface oxide) interface layer 204 formed thereon and a high-k layer 206 formed overlying substrate 202 and/or interface layer 204. A thickness of the interface layer 204 can be between about 5 and about 15 Angstroms. A thickness of the high-k layer can be between about 10 and about 35 Angstroms. As noted above, in the context of a method described herein, a substrate 208 can include substrate 202, interface layer 204, and high-k layer 206.

Structure 200 also includes a liner 210, such as a metal nitride layer. Liner 210 can be a metal nitride layer, such as a transition metal (e.g., titanium) nitride layer. A thickness of liner 210 can be between about 3 and about 10 Angstroms or between 5 and 20 Angstroms.

Layer 212 can be a metal nitride layer as described above and can be formed using steps of method 100. In the illustrated case, metal nitride layer 212 forms a p work function layer.

Structure 200 can additionally include a bulk conductive layer 214. Bulk conductive layer 214 can be formed of, for example, a (e.g., transition) metal nitride, such as a titanium nitride layer.

Structure 200 can further include a bulk (e.g., transition) metal layer 216. Bulk metal layer 216 can be or include, for example, tungsten.

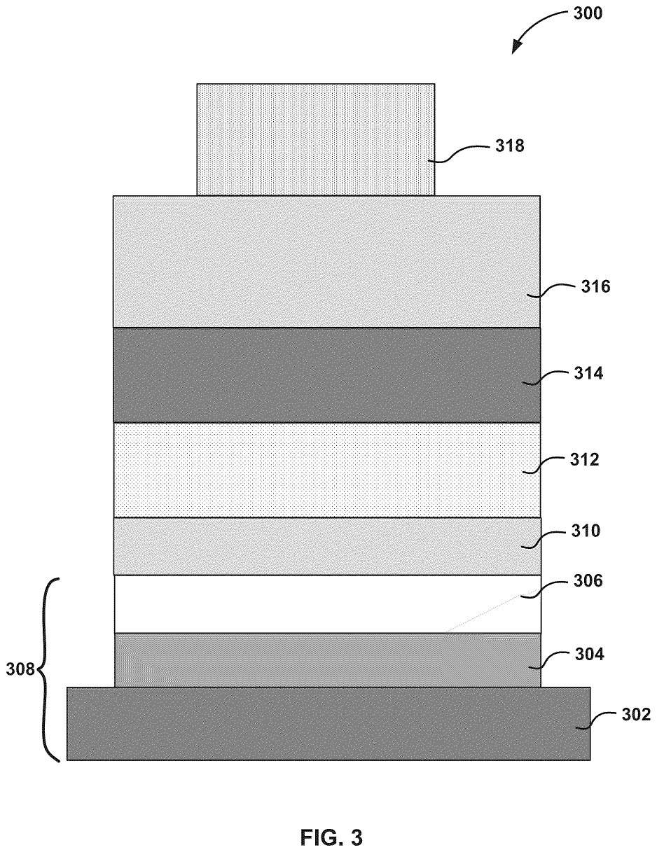

FIG. 3 illustrates another structure 300 in accordance with additional examples of the disclosure. Structure 300 is similar to structure 200, except structure 300 includes an n work function layer 314.

In the illustrated example, structure 300 includes a substrate, a first oxide (e.g., a silicon oxide or interface oxide) layer 304, a high-k layer 306 formed overlying substrate 302 and/or interface layer 204, all of which can be a substrate for use with a method described herein. Structure 300 also includes a liner 310, a p work function layer 312, a bulk conductive layer 316, and a bulk metal layer 318. Substrate 308, liner 310, p work function layer 312, bulk conductive layer 316, and bulk metal layer 318 can be as described above in connection with FIG. 2.

N work function layer 314 can be formed of, for example, a (e.g., transition) metal nitride and/or a (e.g., transition) metal carbide, such as a titanium carbide/titanium nitride material. In this case, work function layer 314 can form part of a blocking stack.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a structure, the method comprising the steps of:
providing a substrate, comprising a high-k layer, within a reaction chamber; and
depositing a metal nitride layer overlying the high-k layer, using a cyclical deposition process, the cyclical deposition process comprising:
providing a metal precursor within the reaction chamber for a precursor pulse; and
providing a hydrogen and nitrogen reactant to the reaction chamber for a reactant pulse,
wherein the metal precursor is represented by the chemical formula: 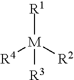
where M is Mo or W, and
where each of R¹-R⁴ is independently selected from a C2-C7═N group or a C2-C7—O group or a C₁-C₄—N group.

2. The method of claim 1, wherein at least two of R¹-R⁴ are independently selected from a C2-C7═N group.

3. The method of claim 2, wherein at least two of R¹-R⁴ are independently selected from a C2-C7—O group.

4. The method of claim 1, wherein the substrate comprises a liner layer overlying and in contact with the high-k layer.

5. The method of claim 4, wherein the liner layer comprises a metal nitride layer.

6. The method of claim 1, further comprising forming a bulk conductive layer overlying and in contact with the metal nitride layer.

7. The method of claim 6, wherein the bulk conductive layer comprises a transition metal nitride.

8. The method of claim 7, further comprising forming a bulk metal layer overlying the bulk conductive layer.

9. The method of claim 1, further comprising forming an n work function layer overlying and in contact with the metal nitride layer.

10. The method of claim 1, wherein the metal nitride layer forms an etch stop layer.

11. The method of claim 1, wherein the metal nitride layer forms a p work function layer.

12. The method of claim 1, wherein the cyclical deposition process further comprises:
purging the reaction chamber after the step of providing the hydrogen and nitrogen reactant; and
after the purging, providing a reducing agent to the reaction chamber.

13. The method of claim 12, wherein the reducing agent is selected from one or more of H₂, 3,6-bis(trimethylsilyl)-1,4-cyclohexadiene, and mixtures thereof.

14. The method of claim 1, wherein a pressure within the reaction chamber during the step of providing a reducing agent to the reaction chamber increases over time.

15. The method of claim 14, wherein the pressure increases by about 30 Torr or more.

16. The method of claim 1, wherein a thickness of the metal nitride layer is less than 20 Angstroms.

17. The method of claim 1, wherein a temperature within the reaction chamber is between about 300° C. and about 450° C.

18. The method of claim 1, wherein the step of depositing the metal nitride layer is a thermal deposition process.

19. The method of claim 1, wherein a resistivity metal nitride layer is less than 650 μOhm.cm.

20. The method of claim 1, wherein at least two of R¹-R⁴ are independently selected from a C1-C4—N group.
